(19) United States
(12) Patent Application Publication
(10) Pub. No.: US 2015/0035123 A1
(43) Pub. Date: Feb. 5, 2015

(54) CURVATURE COMPENSATED SUBSTRATE AND METHOD OF FORMING SAME

(71) Applicant: International Business Machines Corporation, Armonk, NY (US)

(72) Inventors: Can Bayram, Ossining, NY (US); Stephen W. Bedell, Wappingers Falls, NY (US); Devendra K. Sadana, Pleasantville, NY (US)

(73) Assignee: International Business Machines Corporation, Armonk, NY (US)

(21) Appl. No.: 13/956,906

(22) Filed: Aug. 1, 2013

(51) Int. Cl. H01L 21/02; H01L 29/06; H01L 29/20

(52) U.S. Cl. CPC H01L 21/0243; H01L 29/2003; H01L 21/0242; H01L 21/0254; H01L 29/0657
USPC 257/615; 438/481

(57) ABSTRACT

A curvature-control-material (CCM) is formed on one side of a substrate prior to forming a Group III nitride material on the other side of the substrate. The CCM possess a thermal expansion coefficient (TEC) that is lower than the TEC of the substrate and is stable at elevated growth temperatures required for formation of a Group III nitride material. In some embodiments, the deposition conditions of the CCM enable a flat-wafer condition for the Group III nitride material maximizing the emission wavelength uniformity of the Group III nitride material. Employment of the CCM also reduces the final structure bowing during cool down leading to reduced convex substrate curvatures. In some embodiments, the final structure curvature can further be engineered to be concave by proper selection of CCM properties, and via controlled selective etching of the CCM, this method enables the final structure to be flat.

### BACKGROUND

The present application relates to a semiconductor structure and methods of forming the same. More particularly, the present application relates to methods for controlling the curvature of a substrate in which a Group III nitride material will be subsequently formed thereon. The present application also provides a semiconductor structure including a curvature compensated substrate which includes a layer of a Group III nitride material thereon.

Emerging light emitting diodes (LEDs) are key components of an affordable, durable and environmentally benign lighting solution that can perform at superior energy conversion efficiency. LEDs are semiconductor devices that convert electrical energy into optical energy (i.e., LEDs convert electrical charge carriers (electrons and holes) into photons possessing the energy of the active layer material bandgap). Visible light emitting diodes typically employ InGaN as the active layer material. InGaN is a material that can be compositionally tuned to achieve violet, blue, green, and red LEDs. Sapphire is a commercial substrate material employed in the development of light emitting diodes (LEDs) targeting visible spectra (375-750 nm).

However, the cost of LED fixtures (with respect to available technologies such as halogen fixtures) prevents their market penetration. The main cost (approximately 40%) of the LED fixture is the LED die; that is grown conventionally by metal-organic chemical vapor deposition (MOCVD)—an industrial compound semiconductor growth technique.

Current efforts on reducing the LED cost are focused on increasing the production volume and yield. Current state-of-the-art manufacturing facilities mostly employ 4-inch sapphire wafers—much smaller than silicon-based technologies (≧12-inch wafers). Employment of larger area wafers (such as 6-inch) and availability of sapphire wafers up-to 12-inch are promising for the up-scaling that will lead to a significant reduction in the cost of a single LED die.

Thermal mismatch between the sapphire substrate and the LED epilayers (i.e., Group III nitrides such as, for example, AlGaInN) leads to a significant wafer bowing. This wafer bow becomes more pronounced when the wafer diameter is increased. Considering that the temperature cycling between various LED epilayers are on the order of 600° C., the mismatch between the thermal expansion coefficients (TECs) of the substrate and LED epilayers becomes much more significant (especially for LEDs with respect to other technologies such as transistors where lower temperatures and less growth time are required).

Current technologies targeting larger area sapphire wafers development for LED manufacturing focuses on the reactor designs (to compensate for the temperature non-uniformities) and new susceptor (wafer holder) designs (i.e., with bowing space).

Aside from the reactor design optimizations, industry experiments with thicker sapphire wafers (2-inch is 430 μm; 4-inch is 900 μm; and 6-inch is 1300 μm) for increased diameter wafers. This approach aims to benefit from the structural strength (robustness) of the sapphire wafer. Thicker sapphire wafers can withstand further bowing and prevent cracking. However, the wafer bow becomes a uniformity issue rather than a structural issue with this approach: Thicker wafers make the temperature gradient across the substrate (from bottom to top) more significant leading to increased temperature gradient. This increased temperature gradient results in more significant wafer bow that especially reduces the uniformity of the active layer of the LEDs.

In addition, thicker sapphire wafers increase the cost for the wafer (total substrate material amount used per a LED die is increasing almost linearly with the diameter) reducing the advantage of going to a larger wafer diameter.

In summary, available approaches lead to a trade-off between wafer bow at the Group III nitride active layer growth process and wafer bow at the completion of the LED. Thinner substrates suffer from a final LED wafer bow whereas thicker ones suffer from wafer bow related non-uniformity in the active layer. For example, InGaN, which material emits in the entire visible spectrum via increasing the indium content (x) of InₓGa₁₋ₓN, is highly sensitive (exponential) to the deposition temperature and wafer curvature leads to a non-uniformity in wafer temperature leading to non-uniformity in the emission wavelength; hence decreasing the yield for thicker substrates.

### SUMMARY

A curvature-control-material (CCM) is formed on one side of a substrate prior to forming a Group III nitride material on the other side of the substrate. The CCM possess a thermal expansion coefficient (TEC) that is lower than the TEC of the substrate and is stable at elevated growth temperatures required for formation of a Group III nitride material. In some embodiments, the deposition conditions of the CCM enable a flat-wafer condition for the Group III nitride material maximizing the emission wavelength uniformity of the Group III nitride material. Employment of the CCM also reduces the final structure bowing during cool down leading to reduced convex substrate curvatures. In some embodiments, the final structure curvature can further be engineered to be concave by proper selection of CCM properties, and via controlled selective etching of the CCM, this method enables the final structure to be flat.

In one aspect of the present application, methods of controlling curvature of a substrate, i.e., wafer, in which a Group III nitride material will be subsequently formed thereon are provided. In one embodiment, the method includes depositing a curvature-control-material having a first thermal expansion coefficient directly on a surface of a substrate having a second thermal expansion coefficient at a deposition temperature that is greater than room temperature to provide a first planar structure comprising the substrate and the curvature-control-material. In accordance with the present application, the first thermal expansion coefficient of the curvature-control-material is less than the second thermal expansion coefficient of the substrate. Next, the planar structure is cooled from the deposition temperature to room temperature to provide a non-planar structure having a curvature and comprising the substrate and the curvature-control-material. A Group III nitride material having a third thermal expansion coefficient is epitaxially grown on another surface of the substrate that is opposite the surface of the substrate containing the curvature-control-material to provide a second planar structure comprising the Group III nitride material, the substrate and the curvature-control-material. In accordance with the present application, the third thermal coefficient expansion of the Group III nitride material is less than the first thermal coefficient of the substrate.

In another embodiment, the method includes depositing a curvature-control-material having a first thermal expansion coefficient directly on a surface of a substrate having a second thermal expansion coefficient at a deposition temperature that is greater than room temperature to provide a first planar structure comprising the substrate and the curvature-control-material. In accordance with the present application, the first thermal expansion coefficient of the curvature-control-material is less than the second thermal expansion coefficient of the substrate. Next, the planar structure is cooled from the deposition temperature to room temperature to provide a non-planar structure having a curvature and comprising the substrate and the curvature-control-material. A Group III nitride material having a third thermal expansion coefficient is epitaxially grown on another surface of the substrate that is opposite the surface of the substrate containing the curvature-control-material. In accordance with the present application, the third thermal coefficient expansion of the Group III nitride material is less than the first thermal coefficient of the substrate. A portion of the curvature-control-material is then removed to provide a second planar structure comprising the Group III nitride material, the substrate and a reduced thickness curvature-control-material.

The present application also provides a semiconductor structure including a curvature compensated substrate which includes a layer of a Group III nitride material thereon. Specifically, the semiconductor structure of the present application includes a curvature-control-material having a first thermal expansion coefficient located directly on a surface of a substrate having a second thermal expansion coefficient. In accordance with the present application, the first thermal expansion coefficient of the curvature-control-material is less than the second thermal expansion coefficient of the substrate. The structure of the present application also includes a Group III nitride material having a third thermal expansion coefficient located on another surface of the substrate that is opposite the surface of the substrate containing the curvature-control-material, wherein the third thermal coefficient expansion of the Group III nitride material is less than the first thermal coefficient of the substrate.

### BRIEF DESCRIPTION OF THE DRAWINGS

FIG. 1 is a cross sectional view of a substrate that can be employed in accordance with an embodiment of the present application.

FIG. 2 is a cross sectional view of the substrate of FIG. 1 at the deposition temperature in which a curvature-control-material is deposited directly on a surface of the substrate in accordance with an embodiment of the present application.

FIG. 3 is a cross sectional view of the structure of FIG. 2 after providing a curvature to both the substrate and the curvature-control-material by cooling the structure from the deposition temperature to room temperature in accordance with an embodiment of the present application.

FIG. 4 is a cross sectional view of the structure of FIG. 3 after rotating the structure 180° in accordance with an embodiment of the present application.

FIG. 5 is a cross sectional view of the structure of FIG. 4 after epitaxially growing a Group III nitride material on a surface of the substrate not including the curvature-control-material in accordance with an embodiment of the present application.

FIG. 6 is a cross sectional view of the structure of FIG. 5 after removing a portion the layer of curvature control material therefrom.

### DETAILED DESCRIPTION

The present application will now be described in greater detail by referring to the following discussion and drawings that accompany the present application. It is noted that the drawings of the present application are provided for illustrative purposes and, as such, they are not drawn to scale. In the drawings and description that follows, like elements are described and referred to by like reference numerals.

In the following description, numerous specific details are set forth, such as particular structures, components, materials, dimensions, processing steps and techniques, in order to provide a thorough understanding of the present application. However, it will be appreciated by one of ordinary skill in the art that the present application may be practiced with viable alternative process options without these specific details. In other instances, well-known structures or processing steps have not been described in detail in order to avoid obscuring the various embodiments of the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Current state of the art wafer diameters for LED applications is 4-inch despite the availability of 6-, 8-, and 12-inch sapphire wafers. One of the bottlenecks in scaling the wafer size for light emitting diodes is the necessity for maintaining the uniformity across the full wafer. Wafer curvature is the most crucial parameter for improved uniformity and yield.

The conventional approach to prevent wafer bowing in large diameter sapphire wafers is making the substrate thicker. However, this approach increases not only the wafer cost but it also cannot decrease the wafer bow less than 250 μm. In addition, the thermal gradient between the top and bottom of the wafer increases with the thicker substrates leading to reduced uniformity.

The present application provides a method to decrease the wafer bowing of the conventional sapphire substrates used for light emitting diode technologies, which may lead to larger area sapphire wafer employment in LED technology.

Notably, the present application contemplates the use of a curvature-control-material (or stress compensation layer) applied to any substrate where the curvature during growth of a film containing a Group III nitride compromises the film quality. This application is also directed to a method to control the curvature of a substrate. The combination of the curvature-control-material and the substrate can be referred to herein as a curvature compensated substrate. The method of the present application enables final structure flatness at two temperatures (1) at the active Group III nitride material deposition temperature; and (2) at room temperature. Structure flatness at (1) enables uniformity of the Group III nitride material deposition increasing the yield. Structure flatness at (2) enables fabrication ease and uniformity increasing the yield. Throughout the growth (from start to end), the wafer curvature would be less than the conventional approach.

The method of the present application does not require the employment of thicker substrates that lead to active layer non-uniformities. The method of the present application is an ex-situ method that prevents the conventional trade-offs between active layer bowing and the final LED bowing because each bowing can be controlled independently by the ex-situ curvature-control material deposition.

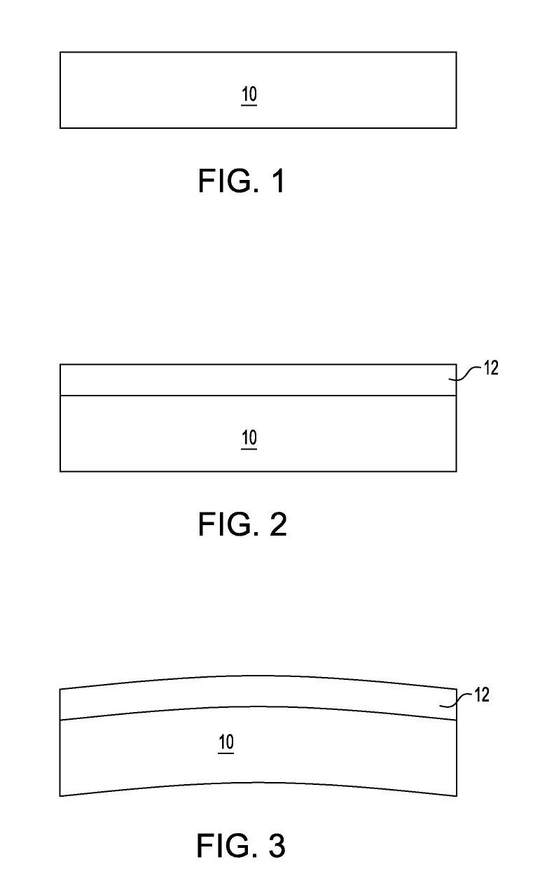

Referring first to FIG. 1, there is illustrated a substrate 10 that can be employed in one embodiment of the present application. The substrate 10 has a first surface and a second surface which is opposite the first surface. The first and second surfaces of the substrate 10 are both planar. The term “planar” used in conjunction with a surface of a material denotes that the surface of the material is straight in two dimensions. Stated in other turns, a planar surface of a material lacks any curvature between two end points.

In some embodiments of the present application, the substrate 10 can comprise a single material having unitary construction. In another embodiment of the present application, the substrate 10 can comprise two or more different materials stacked one atop the other. The substrate 10 or at least an upper portion of the substrate 10 comprises a material in which a Group III nitride material layer can be subsequently formed thereon by metal-organic chemical vapor deposition (MOCVD). Thus, substrate 10 can also be referred to herein as a Group III nitride material growth substrate.

In one embodiment of the present application, substrate 10 can comprise a semiconductor material including for example, (111) silicon, silicon carbide, a Group III nitride material, and a multilayered stack thereof. For example, substrate 10 can comprise a multilayered stack of, from bottom to top, a layer of silicon and an epitaxially grown Group III nitride. The term “Group III nitride” as used throughout the present application denotes a compound of nitrogen and at least one element from Group III, i.e., aluminum (Al), gallium (Ga) and indium (In), of the Periodic Table of Elements. Illustrative examples of some Group III nitride materials that can be employed as substrate 10 include, but are not limited to, GaN, AlN, AlGaN, GaAlN, and GaAlInN. In another embodiment of the present application, substrate 10 can comprise sapphire, i.e., Al₂O₃.

When substrate 10 is comprised of a semiconductor material, the semiconductor material that can be employed in the present application is typically a single crystalline material and may be doped, undoped or contain regions that are doped and other regions that are non-doped. The dopant may be an n-type dopant selected from an Element from Group VA of the Periodic Table of Elements (i.e., P, As and/or Sb) or a p-type dopant selected from an Element from Group IIIA of the Periodic Table of Elements (i.e., B, Al, Ga and/or In). The substrate 10 may contain one region that is doped with a p-type dopant and other region that is doped with an n-type dopant.

The substrate 10 that is employed in the present application can expand in response to heating and contract on cooling. This response to temperature change, which varies depending of the material of the substrate, can be expressed in terms of the materials thermal expansion coefficient (TEC); it is noted that the TECs reported herein are linear TECs. In one example, sapphire has a thermal expansion coefficient (TEC) of about 7.3E⁻⁶/K at 20° C.

The substrate 10 can have a thickness from 5 microns to 2 cm. Thicknesses that are greater than or lesser than the aforementioned thickness range can also be used for the substrate 10.

Referring now to FIG. 2, there is shown the substrate 10 of FIG. 1 at the deposition temperature in which a curvature-control-material 12 is deposited directly on a surface of the substrate 10 in accordance with an embodiment of the present application. As shown, the curvature-control-material 12 covers an entire surface of the substrate 10.

In accordance with the present application, the curvature-control-material 12 that is employed has a lower thermal expansion coefficient than the thermal expansion coefficient of substrate 10. Thus, and at the deposition temperature of the curvature-control-material 12, both the curvature-control-material 12 and the substrate 10 will be under no strain. As such, and at the deposition temperature of the curvature-control-material 12, a planar structure comprising the curvature-control-material 12 and the substrate 10 is provided. By “planar structure” it is meant that the surfaces of the various materials within the structure are straight in two dimensions, i.e., lack any curvature.

The type of curvature-control-material 12 that can be employed in the present application is not limited to any specific material so long as the material that is chosen as the curvature-control-material 12 has a lower thermal expansion coefficient than that of substrate 10 and so long as the curvature-control-material 12 is growth compatible with the surface of substrate 10 in which the curvature-control-material 12 is formed thereon. In some embodiments of the present application, the curvature-control-material 12 can comprise a dielectric material, and/or a semiconductor material. Examples of some curvature-control-material 12 that can be employed in the present application include, but are not limited to, silicon carbide (TEC=4.7E⁻⁶/K at 20° C.), silicon (TEC=3.6E⁻⁶/K at 20° C.), silicon nitride (TEC=3.3E⁻⁶/K at 20° C.) and silicon dioxide (TEC=5.63E⁻⁶/K at 20° C.). In some embodiments, the curvature-control-material 12 includes a single material. In another embodiment, the curvature-control-material 12 can include a multilayered stack of materials.

The curvature-control-material 12 can be deposited by chemical vapor deposition (CVD), plasma enhanced chemical vapor deposition (PECVD), chemical solution deposition, evaporation, or physical vapor deposition (PVD). Alternatively, the curvature-control-material 12 can be deposited using a thermal process such as, for example, thermal oxidation and/or thermal nitridation.

The deposition of the curvature-control-material 12 can be performed at a deposition temperature that is greater than room temperature. The term “room temperature” is used throughout the present application to denote a temperature from 20° C. to 30° C. In one embodiment of the present application, the deposition of the curvature-control-material 12 can be performed at a deposition temperature of from 300° C. to 1000° C.

The thickness of the curvature-control-material 12 can be from 100 nm to 50 μm. Other thicknesses that are greater than or lesser than the thickness range mentioned above can also be employed for the curvature-control-material 12.

Referring now to FIG. 3, there is illustrated the planar structure of FIG. 2 after providing a curvature to both the substrate 10 and the curvature-control-material 12 by cooling the planar structure from the deposition temperature to room temperature in accordance with an embodiment of the present application. The cooling step, with provides the non-planar structure having a curvature as shown in FIG. 3, can be performed by disengaging the heating source used during the deposition of the curvature-control-material 12 and then allowing the structure to cool to room temperature without any cooling means. Alternatively, cooling means such as, for example, a fan, a blower, or even ambient may be used in cooling the structure from the deposition temperature to room temperature.

After cooling from the deposition temperature to room temperature, the non-planar structure that is shown in FIG. 3 has a curvature associated therein. The amount of curvature that is present within the structure is dependent on the type of substrate material 10 and the type of curvature-control-material 12 employed. In one embodiment, a non-planar structure having a curvature of 10 km⁻¹ to 40 km⁻¹ can be provided. The curvature is present at the upper and bottom surfaces of both the substrate 10 and the curvature-control-material 12. The curvature is that is provided is a result of the mismatch in the TECs between the substrate 10 and the curvature-control-material 12. Notably, and since the TEC for the substrate 10 is larger than the TEC for the curvature-control-material 12, the structure including the substrate 10 and curvature-control-material 12 will be under a tensile stress with a convex profile as shown in FIG. 3.

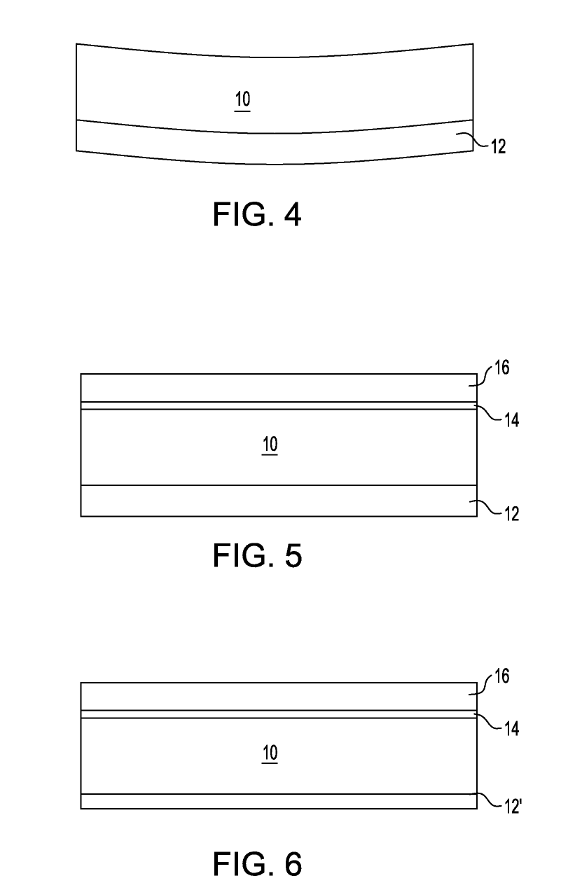

Referring now to FIG. 4, there is illustrated the structure of FIG. 3 after rotating, i.e., flipping, the structure 180° in accordance with an embodiment of the present application. The rotating of the structure may be performed by hand or utilizing any mechanical means such as, for example, a robot arm. After rotating the structure, the profile of the non-planar structure is switched from convex to concave. The rotating of the structure also exposes a surface of the substrate 10 that is opposite the surface of the substrate 10 including the curvature-control-material 12 in which a Group III nitride material can be subsequently formed.

Referring now to FIG. 5, there is illustrated the structure of FIG. 4 after epitaxially growing a Group III nitride material 16 on a surface of the substrate not including the curvature-control-material 12 in accordance with an embodiment of the present application. An optional buffer layer 14 may be formed on the exposed concave surface of substrate 10 prior to forming the Group III nitride material 16. The buffer layer 14 and the Group III nitride material 16 that are formed each have a thermal expansion coefficient that is lower than the substrate 10. In some embodiments, the thermal expansion coefficient of the curvature-control-material 12 is less than the thermal expansion coefficient of either or both the buffer layer 14 and the Group III nitride material 16.

The epitaxial growth of the buffer layer 14 and the Group III nitride material 16 is performed utilizing a metal-organic chemical vapor deposition (MOCVD) process within a MOCVD reactor. The metal-organic chemical vapor deposition (MOCVD) process includes multiple steps including heating up, optional prealuminization, buffer layer formation, and Group III nitride material layer formation.

In some embodiments of the present application, particularly when the substrate 10 includes (111) Si, the structure shown in FIG. 4 may be heated in a hydrogen (or an inert) atmosphere and then a prealuminization process is performed which stabilizes the surfaces of the silicon substrate. In some embodiments, the prealuminization process is omitted and only a heat up step is performed. These steps are performed prior to forming a buffer layer, and prior to forming a Group III nitride material.

The heating of the structure shown in FIG. 4 can be performed by placing the structure into a reactor chamber of a metal-organic chemical vapor deposition (MOCVD) apparatus. The heating of the structure shown in FIG. 4 will preserve the concave curvature profile of the structure. MOCVD can be performed with or without a plasma enhancement provision. In some embodiments, and prior to placing the structure shown in FIG. 4 into the MOCVD reactor chamber, the exposed surface of substrate 10 can be cleaned using an HF cleaning process. The MOCVD reactor chamber including the structure shown in FIG. 4 is then evacuated to a pressure of about 50-100 mbar or less and then a hydrogen atmosphere is introduced into the reactor chamber. In some embodiments, the pressure within the MOCVD reactor is at atmospheric, i.e., 760 mbar. The hydrogen atmosphere may include pure hydrogen or hydrogen admixed with an inert carrier gas such as, for example, helium and/or argon. When an admixture is employed, hydrogen comprises at least 25% or greater of the admixture, the remainder of the admixture (up to 100%) is comprised of the inert carrier gas such as, for example, helium, argon and/or neon.

With the hydrogen atmosphere present in the reactor chamber, the structure is heated to a temperature of about 900° C. or less. In one embodiment, the temperature in which structure shown in FIG. 4 is heated under the hydrogen atmosphere is from 500° C. to 600° C. In another embodiment, the temperature in which the structure shown in FIG. 4 is heated under the hydrogen atmosphere is from 600° C. to 900° C. Notwithstanding the temperature in which the structure shown in FIG. 4 is heated under the hydrogen atmosphere, the heating is performed for a time period of 5 minutes to 20 minutes. This step of the present application is believed to clean the surfaces and hydrogenate the exposed surface of the substrate 10, which may be particularly useful when a (111) silicon substrate is employed. In some embodiments, the heating under hydrogen can be replaced with heating under an inert gas.

Since most Group III elements will react directly with silicon, a prealuminization step is typically performed to stabilize the silicon nucleation sites prior to forming the Group III nitride material; no Al layer is formed during this step of the present application. The prealuminization step can be performed by introducing an organoaluminum precursor such as, for example, a trialkylaluminum compound, wherein the alkyl contains from 1 to 6 carbon atoms, into the reactor chamber. Examples of trialkylaluminum compounds that can be employed in the present application, include, but are not limited to, trimethylaluminum, triethylaluminum, and tributylaluminum. The organoaluminum precursor can be introduced in the reactor chamber of the MOCVD apparatus neat, or it can be admixed with an inert carrier gas. The prealuminization step is typically performed at a temperature of 450° C. or greater. In one embodiment, the introducing of the organoaluminum precursor typically occurs at a temperature from 500° C. to 600° C. In another embodiment, the introduction of the organoaluminum precursor occurs at a temperature from 600° C. to 900° C. Notwithstanding the temperature in which the organoaluminum precursor is introduced into the reactor chamber, the prealuminization is performed for a time period of 5 seconds to 120 seconds.

Next, a buffer layer 14 can be formed on the exposed surface of the substrate 10 shown in FIG. 4. As shown, buffer layer 14 is a contiguous layer that is formed on an entirety of the exposes concave surface of substrate 10 shown in FIG. 4. In some embodiments, especially, when gallium nitride itself is used as the substrate 10, the step of buffer layer formation can be eliminated.

The buffer layer 14 that can be formed at this point of the present application is any Group III nitride material which varies depending on the type of substrate 10 material in which the Group III nitride material will be subsequently formed. For example, and when the substrate 12 is composed of silicon, buffer layer 14 is typically comprised of AlN. When the substrate 10 is comprised of either sapphire or SiC, buffer layer 14 can be comprised of AlN, GaN, or AlGaN. When the substrate 10 is comprised of GaN, no buffer layer need be employed.

Buffer layer 14 is formed by introducing an organo-Group III element containing precursor such as, for example, an organoaluminum precursor (i.e., a trialkylaluminum compound as mentioned above) or an organogallium precursor (i.e., a trialkylgallium compound) or a mixture thereof, and a nitride precursor such as, for example, ammonium nitride into the reactor chamber of the MOCVD apparatus. MOCVD may be carried out with or without a plasma enhancement provision. An inert carrier gas may be present with one of the precursors used in forming the buffer layer 14, or an inert carrier gas can be present with both the precursors used in forming the buffer layer 14. The buffer layer 14 is typically formed at a temperature of 500° C. or greater. In one embodiment, the deposition of the buffer layer 14 typically occurs at a temperature from 650° C. to 850° C. In another embodiment, the deposition of the buffer layer 14 typically occurs at a temperature from 850° C. to 1050° C. Notwithstanding the temperature in which the buffer layer 14 is formed, the deposition of the buffer layer 14 is performed for a time period of 1 minute to 20 minutes. It is noted that the temperatures used for buffer layer 14 formation increases the concave profile of the structure shown in FIG. 4. The buffer layer 14 that is formed typically has a thickness from 10 nm to 250 nm, with a thickness from 60 nm to 80 nm being even more typical.

After forming buffer layer 14, the Group III nitride material 16 is formed. The Group III nitride material 16 may comprise a same or different Group III nitride than the buffer layer 14. The Group III nitride material 16 and the buffer layer 14 have a same crystal structure. Again, the term “Group III nitride material” as used throughout the present application to denote a compound that is composed of nitrogen and at least one element from Group III, i.e., aluminum (Al), gallium (Ga) and indium (In), of the Periodic Table of Elements. Illustrative examples of some common Group III nitrides are AlN, InN, InGaN, GaN, GaAlN, and GaAlInN. In one embodiment of the present application, the Group III nitride material 16 that is formed in the present application is a gallium nitride material such as gallium nitride (GaN), GaAlN, GaInN, and GaAlInN. In another embodiment of the present application, the Group III nitride material 16 that is formed in the present application is an aluminum nitride material such as aluminum nitride (AlN), AlGaN, AlInN, and AlGaInN. Notwithstanding the composition of the Group III nitride material 16 is single crystal.

The Group III nitride material 16 of the present application includes introducing at least one organo-Group III element containing precursor and a nitride precursor such as, for example, ammonium nitride into the reactor chamber of the MOCVD apparatus. MOCVD may be carried out with or without a plasma enhancement provision. Examples of organogallium precursors that can be employed in the present application include trialkylgallium compounds such as, for example, trimethylgallium and triethlygallium. Examples of organoaluminum precursors that can be employed in the present application include trialkylaluminum compounds such as, for example, trimethylaluminum and triethlyaluminum. Similar precursors can be used for other types of Group III nitrides.

An inert carrier gas may be present with one of the precursors used in forming the Group III nitride material 16, or an inert carrier gas can be present with both the precursors used in forming the Group III nitride material 16.

The deposition of the Group III nitride material 16 is typically performed at a temperature of 750° C. or greater. In one embodiment, the deposition of the Group III nitride material 16 typically occurs at a temperature from 900° C. to 1200° C. In another embodiment, the deposition of the Group III nitride material 16 typically occurs at a temperature from 1200° C. to 1400° C. After growing the Group III nitride material 16, the structure containing the same is cooled from the deposition temperature back to room temperature. Notwithstanding the temperature in which the Group III nitride material 16 is formed, the deposition of the Group III nitride material 16 is performed for a time period of 1 minute to 2 hours. The resultant Group III nitride material 16 that is formed has a thickness that is typically from 100 nm to 5000 nm, with a thickness from 500 nm to 1000 nm being even more typical.

After cooling the structure containing the Group III nitride material from the deposition temperature to room temperature, and due to the thermal expansion coefficient (TEC) mismatch between the various layers of the resultant structure, the structure can be under tensile stress from one side containing the Group III nitride 16 and from the other side containing the curvature-control-material 12 leading to a more flat, i.e., planar, structure as these layers oppose to each other. In some embodiments, and immediately after cooling, the curvature-control-material 12, the substrate 10 and the Group III nitride 16 each have planar upper and lower surfaces.

It is important to note that in prior art structures using a conventional sapphire substrate, the final LED structure has a convex profile. Thus, engineering the curvature-control-material 12 that has a smaller thermal expansion coefficient than substrate 10 will lead to significantly reduced convex curvature values, if any.

If the ending curvature-control-material 12-substrate 10 profile of the structure shown in FIG. 5 is concave, then the wafer can be flattened (i.e., made planar) by controlled etching of the curvature-control-material 12 material as shown in FIG. 6. Notably, FIG. 6 shows a structure similar to FIG. 5, but having a concave curvature profile, after removing a portion the layer of curvature-control-material 12 therefrom. The remaining curvature-control-material 12 (which can be referred herein as a reduced thickness curvature-control-material) is designated as 12′ in the drawings. The remaining curvature-control-material 12′ has a thickness that is less than the original thickness of the curvature-control-material 12.

In one embodiment, the removal of a portion of the curvature-control-material 12 from a structure similar to FIG. 5, but having a concave curvature profile, can be performed utilizing a chemical wet etch process. In one example, HF can be used to remove a portion of the curvature-control-material 12 such as silicon dioxide from the structure. In another example, HF and HNO₃ mixture can be used to remove a portion of the curvature-control-material 12 such as silicon from the structure. The removal of a portion of the curvature-control-material 12 from a structure similar to FIG. 5, but having a concave curvature profile, provides another means for providing a completely flat, i.e., planar, structure.

FIGS. 5 and 6 show semiconductor structures of the present application. The structures of the present application include a curvature-control-material 12 (or 12′) having a first thermal expansion coefficient located directly on a surface of a substrate 10 having a second thermal expansion coefficient, wherein the first thermal expansion coefficient of the curvature-control-material 12 (or 12′) is less than the second thermal expansion coefficient of the substrate 10. The structure also includes a Group III nitride material 16 having a third thermal expansion coefficient located on another surface of the substrate 10 that is opposite the surface of the substrate 10 containing the curvature-control-material 12 (or 12′), wherein the third thermal coefficient expansion of the Group III nitride material 16 is less than the first thermal coefficient of the substrate 10.

In one example of the present method, a 450-μm-thick sapphire wafer typically undergoes a wafer bow of 50 μm when growth of a typical LED structure is complete. In order to compensate this final bow, before the growth of the LED on sapphire, one can deposit roughly 0.5-μm-thick SiO₂ at 600° C. on the back-side of the sapphire. When it cools down, SiO₂ has roughly 2 GPa stress leading to a roughly 50 μm bow of opposite sign.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A method of controlling curvature of a substrate in which a Group III nitride material will be subsequently formed thereon, said method comprising:
depositing a curvature-control-material having a first thermal expansion coefficient directly on a surface of a substrate having a second thermal expansion coefficient at a deposition temperature that is greater than room temperature to provide a first planar structure comprising the substrate and the curvature-control-material, wherein the first thermal expansion coefficient of the curvature-control-material is less than the second thermal expansion coefficient of the substrate;
cooling the planar structure from the deposition temperature to room temperature to provide a non-planar structure having a curvature and comprising the substrate and the curvature-control-material; and
epitaxially growing a Group III nitride material having a third thermal expansion coefficient on another surface of the substrate that is opposite the surface of the substrate containing the curvature-control-material to provide a second planar structure comprising the Group III nitride material, the substrate and the curvature-control-material, wherein the third thermal coefficient expansion of the Group III nitride material is less than the first thermal coefficient of the substrate.

2. The method of claim 1, wherein said deposition temperature of said curvature-control-material is from 300° C. to 1000° C.

3. The method of claim 1, wherein said non-planar structure having said curvature has a convex profile.

4. The method of claim 1, wherein said epitaxially growing said Group III nitride material comprises metal-organic chemical vapor deposition.

5. The method of claim 4, wherein said metal-organic chemical vapor deposition comprises a heating step in hydrogen or an inert atmosphere, buffer layer formation and Group III nitride formation.

6. The method of claim 4, wherein said metal-organic chemical vapor deposition is performed at a growth temperature which maintains curvature of said non-planar structure, and upon cooling to room temperature the curvature is completely eliminated.

7. A method of controlling curvature of a substrate in which a Group III nitride material will be subsequently formed thereon, said method comprising:
depositing a curvature-control-material having a first thermal expansion coefficient on a surface of a substrate having a second thermal expansion coefficient at a deposition temperature that is greater than room temperature to provide a first planar structure comprising the substrate and the curvature-control-material, wherein the first thermal expansion coefficient of the curvature-control-material is less than the second thermal expansion coefficient of the substrate;
cooling the planar structure from the deposition temperature to room temperature to provide a non-planar structure having a curvature and comprising the substrate and the curvature-control-material;
epitaxially growing a Group III nitride material having a third thermal expansion coefficient on another surface of the substrate that is opposite the surface of the substrate containing the curvature-control-material, wherein the third thermal coefficient expansion of the Group III nitride material is less than the first thermal coefficient of the substrate; and
removing a portion of the curvature-control-material to provide a second planar structure comprising the Group III nitride material, the substrate and a reduced thickness curvature-control-material.

8. The method of claim 7, wherein said deposition temperature of said curvature-control-material is from 300° C. to 1000° C.

9. The method of claim 7, wherein said non-planar structure having said curvature has a convex profile.

10. The method of claim 7, wherein said epitaxially growing said Group III nitride material comprises metal-organic chemical vapor deposition.

11. The method of claim 10, wherein said metal-organic chemical vapor deposition comprises a heating step in hydrogen or an inert atmosphere, buffer layer formation and Group III nitride formation.

12. The method of claim 10, wherein said metal-organic chemical vapor deposition is performed at a growth temperature which maintains curvature of said non-planar structure, and upon cooling to room temperature the curvature is still maintained.

13. The method of claim 7, wherein said removing the portion of the curvature-control-material comprises a chemical wet etch.

14. A semiconductor structure comprising:
a curvature-control-material having a first thermal expansion coefficient located directly on a surface of a substrate having a second thermal expansion coefficient, wherein the first thermal expansion coefficient of the curvature-control-material is less than the second thermal expansion coefficient of the substrate; and
a Group III nitride material having a third thermal expansion coefficient located on another surface of the substrate that is opposite the surface of the substrate containing the curvature-control-material, wherein the third thermal coefficient expansion of the Group III nitride material is less than the first thermal coefficient of the substrate.

15. The semiconductor structure of claim 14, wherein said substrate is sapphire.

16. The semiconductor structure of claim 15, wherein said curvature-control-material is one of silicon dioxide, silicon carbide, silicon, and silicon nitride.

17. The semiconductor structure of claim 14, further comprising a buffer layer positioned between said another surface of the substrate and said Group III nitride material.

18. The semiconductor structure of claim 17, wherein said buffer layer and said Group III nitride material have a same crystal structure.

19. The semiconductor structure of claim 14, wherein said Group III nitride material is single crystalline.

20. The semiconductor structure of claim 14, wherein said curvature-control-material, said substrate and said Group III nitride each have planar upper and lower surfaces.
